(19) United States
(12) Patent Application Publication
(10) Pub. No.: US 2014/0196766 A1
(43) Pub. Date: Jul. 17, 2014

(54) SOLAR PANEL

(71) Applicants: Holger Schumacher, Grevenbroich (DE); Hans-Werner Kuster, Aachen (DE); Dang Cuong Phan, Aachen (DE)

(72) Inventors: Holger Schumacher, Grevenbroich (DE); Hans-Werner Kuster, Aachen (DE); Dang Cuong Phan, Aachen (DE)

(21) Appl. No.: 14/116,495

(22) PCT Filed: Mar. 30, 2012
(86) PCT No.: PCT/EP2012/055802

§ 371 Date: Jan. 16, 2014

(30) Foreign Application Priority Data
May 19, 2011 (EP) 11166653.3

(51) Int. Cl. H01L 31/048; H01L 31/042

(52) U.S. Cl. CPC H01L 31/0484; H01L 31/0424
USPC 136/251; 438/67

(57) ABSTRACT

A solar panel is described. The solar panel has at least a) a support layer, b) a first intermediate layer, arranged on top of the support layer, c) at least one crystalline solar cell, arranged on top of the intermediate layer, d) a second intermediate layer, arranged on top of the crystalline solar cell, e) a front pane from glass having a thickness of 0.85 to 2.8 mm, arranged on top of the second intermediate layer, and f) an edge reinforcing structure. The edge reinforcing structure projects from the front pane by a height of at least 0.5 mm and has at least one drain channel in every corner of the solar panel. The drain channel connects the interior and the exterior of the edge reinforcing structure.

The invention relates to a lightweight solar module, a method for producing a lightweight solar module, and a flat roof with a solar module.

Photovoltaic layer systems for the direct conversion of sunlight into electrical energy are sufficiently well known. The materials and the arrangement of the layers are coordinated such that incident radiation is converted directly into electrical current by one or a plurality of semiconducting layers with the highest possible radiation yield. Photovoltaic and extensive-area layer systems are referred to as solar cells.

Solar cells contain, in all cases, semiconductor material. The highest efficiency levels known to date of more than 20% are obtained with high-performance solar cells made of monocrystalline, polycrystalline, or microcrystalline silicon or gallium arsenide. More than 80% of the currently installed solar cell power is based on crystalline silicon.

An electrical circuit of a plurality of solar cells is referred to as a photovoltaic module or a solar module. The circuit of solar cells is durably protected against environmental influences in known weather-resistant superstructures. Usually, two panes made of low-iron soda lime glass and adhesion-promoting polymer films are connected to the solar cells to form a weather-resistant solar module. The solar modules can be integrated via connection boxes into a circuit of a plurality of solar modules. The circuit of solar modules is connected to the public supply network or to an independent electrical energy supply via known power electronics.

Flat roofs of warehouses or industrial plants have a large, exposed, shadow-free area. Consequently, they are particularly well-suited for the installation of photovoltaic systems. The roofing membrane of flat roofs consists, as a rule, of metal sheets and, for example, trapezoidal metal sheets. Flat roofs customarily have only a slight pitch of 2% to 17.6% and have only a low load-bearing capacity of, for example, 75 kg/m².

Solar modules according to the prior art, in which the solar cells are laminated between two panes made of soda lime glass, have a high weight per area of, for example, 18 kg/m². Consequently, they are unsuitable for installation on flat roofs with a low load-bearing capacity.

US 2010/0065116 A1 discloses a thin glass solar module with a weight per area of 5 kg/m² to 10 kg/m². The thin glass solar module comprises a carrier layer, solar cells, and a front pane made of very thin, chemically strengthened glass. The very thin glass is flexible. The front pane is so flexible that the impact energy of a hailstone in the legally prescribed hail impact test is absorbed by the carrier layer on the back side of the solar module.

Such a structure is unsuitable for high-performance solar cells made of crystalline silicon. The crystalline silicon is brittle and would break due to the deflection of the front pane. This results, as a rule, in the destruction of large region of the solar cell, even when the front pane is so flexible that it is undamaged.

DE 10 2009 016 735 A1 describes a solar module with a front pane and a back pane, wherein one of the panes has a thickness of at least 3 mm and the other has a maximum thickness of 2 mm.

EP 1 860 705 A1 discloses a stable, self-supporting solar module that is arranged on its outer regions in a mounting frame. The mounting frame has notches through which liquids situated on the solar module can drain off.

JP 2009141216 A discloses a solar module that is arranged in a U-shaped frame. An elastic material is arranged between the solar module and the U-shaped frame. The U-shaped frame and the elastic material have, in at least one place, cutouts that enable the draining of liquids situated on the solar module.

FR 2 922 363 A1 relates to a method for sealing a solar module wherein the front pane and the back pane have a gap to accommodate a sealant.

U.S. Pat. No. 4,830,038 A describes a solar module that is supported and encapsulated by an elastomer. The elastomer is cast in an injection molding process around the back, the sides, and a portion of the front.

DE 10 2008 049 890 A1 discloses a photovoltaic arrangement with a transparent plastic layer and a photovoltaic module arranged on one side of the transparent plastic layer. The photovoltaic module has at least one photovoltaic cell that is arranged between a front cover layer facing the transparent plastic layer and a back cover layer turned away from the plastic layer.

DE 35 13 910 A1 describes a solar module in which at least one solar cell is embedded in plastic. At least one device for mounting the solar module is arranged in the edge region of the plastic.

The object of the present invention consists in providing a solar module having crystalline solar cells that is lightweight and is suited in particular for installation on a flat roof.

The object of the present invention is accomplished according to the invention by a solar module in accordance with claim 1. Preferred embodiments emerge from the subclaims.

The invention further comprises a method for producing a solar module.

A use of the solar module according to the invention emerges from other claims.

The solar module according to the invention comprises

a) a carrier layer,

b) a first intermediate layer, which is arranged, at least in sections, above der carrier layer,

c) at least one crystalline solar cell, which is arranged above the first intermediate layer,

d) a second intermediate layer, which is arranged above the crystalline solar cell,

e) a front pane, made of glass with a thickness of 0.85 to 2.8 mm, which is arranged above the second intermediate layer, and

f) an edge reinforcement, wherein the edge reinforcement (7) projects beyond the front pane (6) by a height (h) of at least 0.5 mm and the edge reinforcement has on each corner of the solar module at least one water drain channel that connects the internal side of the edge reinforcement to the external side of the edge reinforcement.

In an advantageous embodiment of the invention, the front pane includes a partially prestressed or prestressed glass, preferably a thermally partially prestressed or prestressed or a strengthened glass, for example, a thermally or chemically strengthened glass.

The front pane preferably has a thickness of 0.9 mm to 2.6 mm, particularly preferably of 0.9 mm to 1.5 mm.

In an advantageous embodiment of the invention, the crystalline solar cell comprises a monocrystalline or a polycrystalline solar cell, preferably with a doped semiconductor material such as silicon or gallium arsenide. Alternatively, the crystalline solar cell comprises a tandem cell made of a crystalline solar cell and another solar cell, for example, a thin-film solar cell, an organic solar cell, or an amorphous or microcrystalline silicon solar cell.

In an advantageous embodiment of the invention, the crystalline solar cell comprises all solar cells which are themselves brittle and/or whose carrier material is brittle and which break or are damaged by slight deflection or spot loading with low forces. In this case, a slight deflection means, for example, a curve with a radius of curvature of less than 1500 mm. In this case, spot loading with low forces means, for example, an indentation from the impact of a hailstone with a diameter of 25 mm and a speed of 23 m/s in a hail impact test. Damage means a degradation of the photovoltaic properties of the solar cell due to mechanical damage of the semiconductor material, of the carrier material, or electrical line connections, for example, by a short-circuit or a power interruption. The damage degrades the photovoltaic properties of the solar cell. The damage to the solar cell reduces the efficiency level of the solar cell, for example, immediately after the impact by, for example, more than 3%. Usually, a further degradation of the efficiency level takes place due to microcracks over the course of time.

The first and/or second intermediate layer contains an adhesive layer, preferably one or a plurality of adhesive films, particularly preferably made of ethylene vinyl acetate (EVA), polyvinyl butyral (PVB), ionomers, thermoplastic polyurethane (TPU), thermoplastic elastomer polyolefin (TPO), thermoplastic elastomer (TPE), or other materials with appropriate adhesive and moisture-proofing properties. The thickness of an adhesive layer can vary widely and is preferably from 0.2 mm to 1 mm and, in particular, 0.4 mm.

The external dimensions of the solar module according to the invention can vary widely and are preferably from 0.6 m×0.6 m to 1.2 m×2.4 m. A solar module according to the invention preferably includes from 6 to 100 solar cells or solar cell arrays. The area of an individual solar cell is preferably from 153 mm×153 mm to 178 mm×178 mm.

The front pane preferably includes thermally partially prestressed or prestressed glass with a prestress of 30 MPa to 120 MPa and preferably of 32 MPa to 85 MPa. The front pane preferably includes soda lime glass, low-iron soda lime glass, or borosilicate glass. The front pane can have other additional coatings, such as antireflective layers, anti-adhesive layers, or anti-scratch layers. The front pane can be a single glass or a laminated glass made of one or a plurality of panes. A front pane made of a laminated glass can include additional layers, such as transparent thermoplastic adhesive layers.

The front pane of a solar module according to the invention must be adequately stable and inflexible to protect the underlying crystalline solar cells against damage. Possible causes of damage are hail impact, wind load, snow load, or bending during installation as well as being stepped on by people or animals, or the dropping of a tool. At the same time, the front pane should be as thin as possible and have a low weight in order to be suitable for installation on flat roofs with low load-bearing capacity.

As experiments of the inventor have demonstrated, solar modules according to the invention with front panes made of partially prestressed or prestressed glass with a thickness of at least 0.85 mm satisfy the technical demands with regard to torsional rigidity and stability.

A structure with a flexible front pane according to the prior art is not suitable for high-performance solar cells made of crystalline silicon. The crystalline silicon is brittle and would break due to bending of the front pane. This results, as a rule, in the destruction of a large region of the solar cell, even when the front pane is so flexible that it is not damaged.

The thickness of the front pane substantially determines the weight of the solar module. In order to provide the most lightweight possible solar module suitable for installation on a flat roof with only a low loadbearing capacity, front panes with a thickness of a maximum of 2.8 mm are preferably used. A solar module according to the invention with a front pane with a thickness of 2.8 mm has a weight per area of roughly 10 kg/m². Such a solar module is thus suitable for installation on flat roofs with a low loadbearing reserve of at least 10 kg/m².

The front pane preferably has a thickness from 0.9 mm to 2.6 mm, particularly preferably from 0.9 mm to 1.5 mm.

Front panes according to the invention with a thickness of at least 0.85 mm offer, in particular, adequate protection for the crystalline solar cells included in the solar module in the hail impact test according to IEC 61215. The hail impact test includes bombarding the front side of the solar module with hailstones with a diameter of 25 mm and a speed of 23 m/s. The front pane according to the invention has adequate stability and inflexibility to absorb the energy of the impact of a hailstone without the crystalline solar cell being damaged.

The front pane itself according to the invention is not damaged by the hail impact test so long as the hail impact does not occur in an edge region. The edge regions of glass panes are particularly sensitive to flaking and conchoidal fractures, for example, with striking of a hailstone in the hail impact test.

The edge reinforcement according to the invention projects upward by a height h beyond the front pane. The height h is at least 0.5 mm, preferably at least 0.75 mm, and particularly preferably 1 mm to 5 mm. A protected region is created by means of the superelevation of the edge reinforcement beyond the front pane. Because of the superelevation h of the edge reinforcement, a hailstone with a diameter of, for example, 25 mm cannot penetrate into the particularly damage susceptible edge region of the front pane. The height h can be determined by simple experiments in the hail impact test.

In an alternative embodiment, the solar module according to the invention includes an edge reinforcement that preferably covers at least one peripheral edge region of the front pane over a width (b) of at least 0.2 cm, preferably of at least 0.5 cm. The edge reinforcement according to the invention protects the edge region of the front pane against damage in the hail impact test.

The edge reinforcement includes one or a plurality of layers, preferably made from metal, glass, rubber, plastic, or glass fiber reinforced plastic. The edge reinforcement particularly preferably includes the material of the carrier layer. The edge reinforcement preferably has a coefficient of thermal expansion adapted to the solar module and the front pane. As a result, only slight or no mechanical stresses appear due to different thermal expansions.

Since the edge reinforcement projects upward above the front pane, a border that surrounds the front pane is formed. In the event of rainfall or snowmelt, it is possible for water to collect in the region of the transition between the front pane and the edge reinforcement, which water cannot drain off because of the surrounding edge reinforcement. The stagnant water accumulation promotes the formation of algae. Moreover, the long-term effects of water can strain the moisture seals of the solar module. Also, dirt, sand, and dust that cannot be washed away by rainwater collect in this region.

The collection of water and dirt at the transition between the front pane and the edge reinforcement especially concerns solar modules on roofs that have only a slight pitch, so-called flat roofs.

Consequently, an important aspect of the present invention comprises water drain channels that are incorporated into the edge reinforcement. By means of the water drain channels, rainwater or melt water can drain off. The draining water can carry dirt, sand, and dust with it and keep the front pane of the solar module free of contaminants.

In the solar module according to the invention, the edge reinforcement has, on each corner of the solar module, at least one water drain channel that connects the internal side of the edge reinforcement to the external side of the edge reinforcement. Here, “external side of the edge reinforcement” means the side of the edge reinforcement that is situated on the exterior of the solar module. “Internal side of the edge reinforcement” means the side opposite the external side of the edge reinforcement.

In an advantageous embodiment of the solar module according to the invention, the edge reinforcement has at least one water drain channel on each peripheral external side of the solar module.

The width of the water drain channel is advantageously selected such that a hailstone with a diameter of 25 mm at a speed of 23 m/s with a central impact on the water drain channel does not damage the front pane. The width of the water drain channel depends on the height of the superelevation of the edge reinforcement beyond the front pane and can be determined by simple experiments.

In an advantageous embodiment of the solar module according to the invention, the water drain channel (8.1, 8.2) has a width (d) from 0.5 mm to 5 mm, preferably from 2.5 mm to 5 mm.

An important aspect of the invention comprises the adaptation of the coefficient of thermal expansion of the front pane and the carrier layer: Different coefficients of thermal expansion of the front pane and the carrier layer can, with temperature changes, result in different thermal expansion. A different thermal expansion of the front pane and the carrier layer can result in a deflection of the solar module and, thus, in damage to the crystalline solar cells. Temperature changes of more than 100° C. occur, for example, during lamination of the solar module or during warming of the solar module on the roof.

The second coefficient of thermal expansion, i.e., the coefficient of thermal expansion of the front pane, is preferably from 8×10⁻⁶/K to 10×10⁻⁶/K and for partially prestressed soda lime glass, for example, from 8×10⁻⁶/K to 9.3×10⁻⁶/K.

The difference between the first coefficient of thermal expansion of the carrier layer of a solar module according to the invention and the second coefficient of thermal expansion of the front pane is 300%, preferably 200%, and particularly preferably 50% of the second coefficient of thermal expansion of the front pane.

In an advantageous embodiment of the solar module according to the invention, the carrier layer includes a glass fiber reinforced plastic. The glass fiber reinforced plastic includes, for example, a multilayer glass fiber fabric that is embedded in a cast resin molding material made of unsaturated polyester resin. The glass content of the glass fiber reinforced plastic is preferably from 30% to 75% and particularly preferably from 50% to 75%.

In an advantageous embodiment of the solar module according to the invention, the carrier layer has a first coefficient of thermal expansion from 7×10⁻⁶/K to 35×10⁻⁶/K, preferably from 9×10⁻⁶/K to 27×10⁻⁶/K, and particularly preferably from 9×10⁻⁶/K to 20×10⁻⁶/K.

In another advantageous embodiment of the solar module according to the invention, the difference between the first coefficient of thermal expansion and the second coefficient of thermal expansion is 17%, preferably 12%, and particularly preferably 7% of the second coefficient of thermal expansion.

In an alternative embodiment of the solar module according to the invention, the carrier layer includes a metal foil with a first coefficient of thermal expansion from 7.3×10^{31 6}/K to 10.5×10⁻⁶/K. The first intermediate layer preferably includes a stack sequence of at least one first adhesive layer, one insulating layer, and one second adhesive layer. The insulating layer preferably includes a solid insulating film, made, for example, of polyethylene terephthalate (PET). The insulating layer has the task of insulating the busbars and the back side of the solar cells from the electrically conductive metal foil of the carrier layer. The metal foil preferably includes a stainless steel, preferably a high-grade steel of the EN material numbers 1.4016, 1.4520, 1.4511, 1.4017, 1.4113, 1.4510, 1.4516, 1.4513, 1.4509, 1.4749, 1.4724, or 1.4762.

In an advantageous embodiment of the solar module according to the invention, the carrier layer has a peripheral projection beyond the front pane of at least 0.3 cm, preferably of 0.5 cm to 5 cm, and particularly preferably of 1 to 2 cm. The edge reinforcement layer can be arranged on the projection and, for example, be adhesively bonded to the projection. By this means, a secure fastening of the edge reinforcement and additional protection of the external edge of the solar module are obtained.

Another aspect of the invention comprises a flat roof with

a) a roofing membrane with a pitch of 1% (0.6°) to 23.1% (13°),

b) at least one solar module according to the invention, arranged on the roofing membrane, wherein the roofing membrane and the solar module according to the invention are connected to each other at least in sections by at least one adhesive layer and/or connecting means.

In an advantageous embodiment of the flat roof according to the invention, the pitch is from 2% (1.1°) to 17.6% (10°), preferably from 5% (2.9°) to 17.6% (10°), and particularly preferably from 5% (2.9°) to 8.8% (5°).

The adhesive layer, with which the solar module according to the invention and the roofing membrane are connected, preferably includes acrylate adhesives, a buthyl adhesive, a bitumen adhesive, or a silicone adhesive or a double-sided adhesive film. The connecting means preferably include screw, clamp, or rivet connections and/or retaining rails, guide rails, or eyelets made of plastic or metal, such as aluminum, steel, or stainless steel.

In an advantageous embodiment of the flat roof according to the invention, the roofing membrane includes a plastic, preferably polymethyl methacrylate (PMMA, Plexiglas®), polyester, bitumen, polymer-modified bitumen, polyvinyl chloride (PVC), or thermoplastic olefin elastomers (TPOs), preferably with a flat, box-shaped, or corrugated profile.

In an alternative embodiment, the roofing membrane includes a metal sheet, preferably a metal sheet made of copper, aluminum, steel, galvanized steel, and/or plastic-coated steel. The metal sheet has, for example, a trapezoidal profile and is referred to in the following as “trapezoidal metal sheet”. Additional layers can be arranged over or under the roofing membrane, for example, layers for thermal insulation. The layers for thermal insulation preferably include plastics or plastic foams, for example, made of polystyrene or polyurethane.

The bolt connection of the solar module to the roofing membrane of a flat roof according to the invention is preferably carried out in a region of the edge reinforcement of the solar module and, in particular, in the region of the projection of the carrier layer beyond the front pane. This has the particular advantage that no hole need be incorporated in the front pane. Incorporating a hole in the glass front pane is a time-consuming, cost-intensive process step. Moreover, a hole weakens the glass front pane and reduces the stability of the solar module.

Another aspect of the invention comprises a method for producing a solar module according to the invention, wherein at least:

a) a first intermediate layer is arranged above a carrier layer,

b) at least one crystalline solar cell is arranged on the first intermediate layer and the crystalline solar cell is connected to busbars,

c) a second intermediate layer is arranged above the crystalline solar cell, and a front pane is arranged above the second intermediate layer,

d) the layer sequence made up of the first intermediate layer, the carrier layer, the crystalline solar cell, the second intermediate layer, and the front pane is laminated in an autoclave known per se, a vacuum laminator, or a thermal laminator,

f) an edge reinforcement on a projection of the carrier layer is arranged over the front pane, with the edge reinforcement overlapping the front pane in sections.

The lamination takes place, for example, at a temperature of 100° C. to 170° C. and over a period of 7 min. to 25 min.

In an advantageous embodiment of the method according to the invention, the edge reinforcement is formed from at least one height-compensating, first edge reinforcement layer and at least one second edge reinforcement layer overlapping the front pane in sections in an edge region. The first edge reinforcement layer and the second edge reinforcement layer are bonded by adhesive layers to each other and to the laminated layer sequence of process step d).

In an advantageous embodiment of the method according to the invention, the edge reinforcement is arranged before process step d) and is bonded to the layer sequence by means of the lamination procedure in process step d).

In an alternative embodiment of the method according to the invention, a strand with the cross-section of the edge reinforcement is extruded, the strand is divided into segments, and water drain channels are incorporated in the segments. Then, the segments of the edge reinforcement are bonded to the laminated layer sequence from process step d), for example, adhesively bonded. The segments can have the length of a single side of the solar module such that the edge reinforcement of a solar module is formed by a total of four segments. Alternatively, a segment can have the length of the perimeter around the solar module and be arranged in one piece on the solar module.

The edge reinforcement is extruded by extrusion methods known per se, in which plastics or other viscous, curable materials are pressed through a specially shaped nozzle in a continuous process. A strand of any length with the cross-section of the nozzle is created. The plastics can be thermoplastic plastics that are heated during the extrusion.

The water drain channels are preferably introduced by cutting or milling into the surface of the segments. The water drain channels can be introduced into the surface of the segments during the extrusion, for example, by a movable mold. Alternatively, the water drain channels can be incorporated after extrusion and before bonding to the laminated layer sequence. In another alternative, the water drain channels can be introduced after the bonding to the laminated layer sequence.

Extruded edge reinforcements preferably include polyvinyl chloride (PVC), polyethylene (PE), polypropylene (PP), polyamide (PA), high-density polyethylene (HDPE), low-density polyethylene (LDPE), acrylonitrile-butadiene-styrene copolymer (ABS), polycarbonate (PC), styrene butadiene (SB), polymethyl methacrylate (PMMA), polyurethane (PUR), and polyethylene terephthalate (PET).

In an alternative embodiment of the method according to the invention, the edge reinforcement is produced by reaction injection molding (RIM) or by an injection molding process.

In the method known per se of reaction injection molding (RIM), two components (and possibly other additives) are mixed intensively in a mixer and then immediately injected as a reaction molding compound into a shaping mold. Curing occurs in the shaping mold. The water drain channels can already be defined by the shaping mold or can be introduced after curing into the blank of the edge reinforcement.

Particularly suitable for production of an edge reinforcement by reaction injection molding are plastics such as polyurethane (PUR), high-density polyethylene (HDPE), low-density polyethylene (LDPE), polyurea, and polyisocyanurate (PIR).

In the injection molding method known per se, melts of thermoplastic plastics are preferably pressed in a shaping mold. The water drain channels can be defined already by means of the mold or introduced after curing in the blank of the edge reinforcement.

The edge reinforcement can be shaped both by reaction injection molding (RIM) and shaped directly around the laminated sequence as process step d) by the injection molding process and bonded thereto. Alternatively, the edge reinforcement can be formed and bonded in a second step to the laminated layer sequence of d).

Another aspect of the invention comprises the use of a solar module according to the invention on a flat roof, preferably on a metal flat roof of a building or a vehicle for transportation on water, on land, or in the air. Flat roofs of warehouses, industrial plants, and garages or shelters such as carports that have a large, exposed, shadow-free area and a low roof pitch are especially suitable for the installation of solar modules according to the invention.

Another aspect of the invention comprises the use of the solar module according to the invention on a flat roof with a pitch from 1% (0.6°) to 23.1% (13°), preferably from 2% (1.1°) to 17.6% (10°), particularly preferably from 5% (2.9°), to 17.6% (10°), and very particularly preferably from 5% (2.9°) to 8.8% (5°).

### BRIEF DESCRIPTION OF THE DRAWINGS

The invention is explained in detail in the following with reference to drawings and an example. The drawings are not completely true to scale. The invention is in no way restricted by the drawings.

They depict:

FIG. 1A a schematic view of an exemplary embodiment of a solar module according to the invention,

FIG. 1B a cross-sectional view along the section line A-A′ of FIG. 1A,

FIG. 1C a cross-sectional view along the section line B-B′ of FIG. 1A,

FIG. 2A a cross-sectional view of an exemplary embodiment of a solar module according to the invention along the section line A-A′ of FIG. 1A,

FIG. 2B a detail of FIG. 2A with a hailstone in the hail impact test,

FIG. 3 a cross-sectional view of the layer structure of an alternative exemplary embodiment of the solar module according to the invention,

FIG. 4A a cross-sectional view of a flat roof according to the invention,

FIG. 4B a cross-sectional view of an alternative embodiment of a flat roof according to the invention,

FIG. 4C a cross-sectional view of another alternative embodiment of a flat roof according to the invention, and

FIG. 5 a detailed flow chart of the method according to the invention.

### DETAILED DESCRIPTION OF THE DRAWINGS

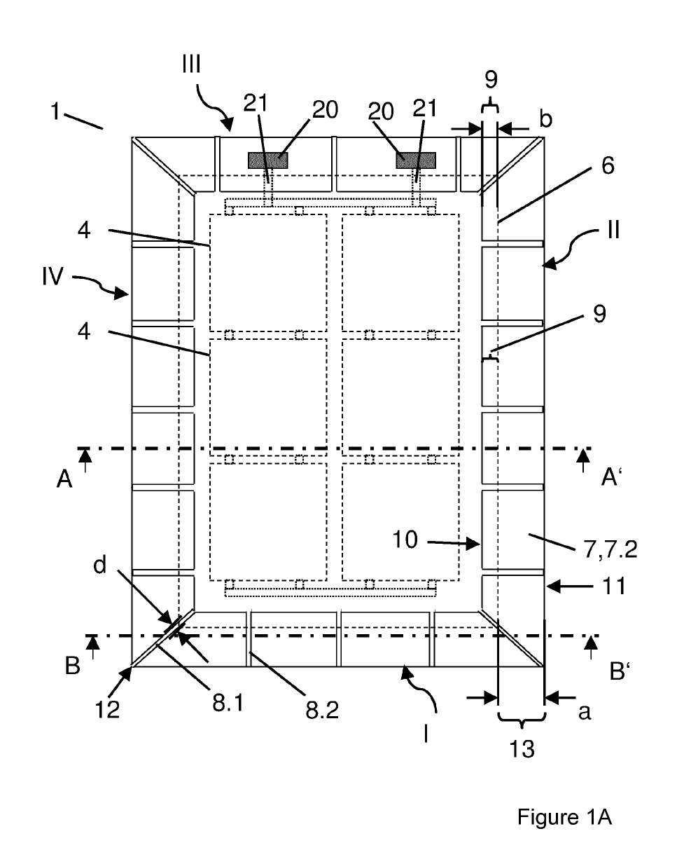

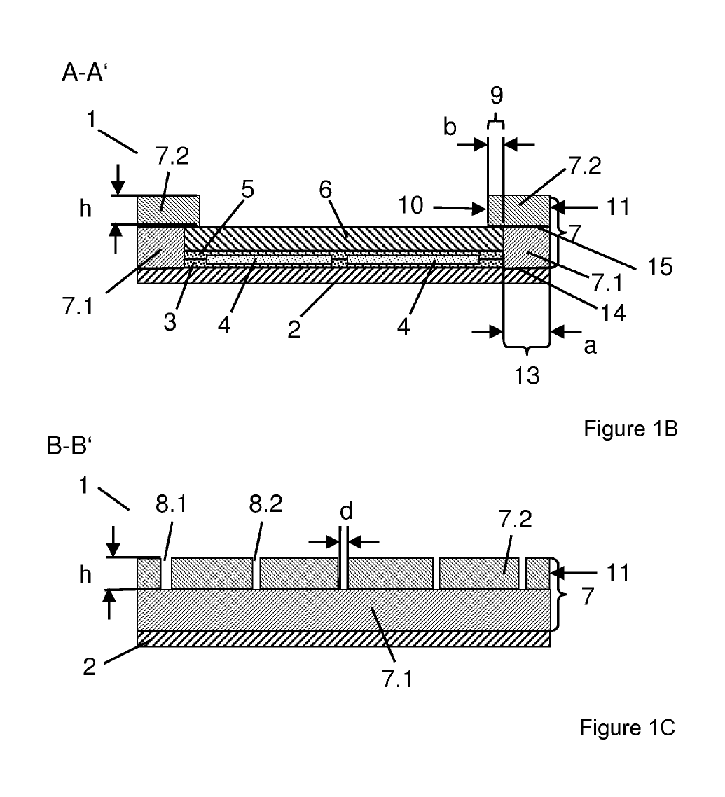

FIG. 1A illustrates a solar module according to the invention referred to as a whole by the reference number 1. FIG. 1A depicts a top view of the front, i.e., of the side facing the sun, of the solar module. The back of the solar module 1 is, in the context of the present invention, the side facing away from the front. The sides surrounding the front and the back are referred to in the following as external sides I, II, Ill, IV of the solar module 1.

The solar module 1 comprises a plurality of serially connected solar cells 4, of which six are depicted in FIG. 1A. The solar cells 4 are, in this example, monocrystalline silicon solar cells. Each solar cell has a nominal voltage of, for example, 0.65 V, such that the solar module 1 has a total nominal voltage of 3.8. The voltage is guided out via two busbars 21 to two connection housings 20 in the edge region of the solar module 1. The electrical connection to the power grid or to other solar modules (not shown here) takes place in the connection housings 20.

FIG. 1B depicts a cross-sectional view along the section line A-A′ of FIG. 1A. The layer structure of the solar module 1 according to the invention is discernible from FIG. 1B. The solar module 1 includes a carrier layer 2 made, for example, of a glass fiber reinforced plastic. The glass fiber reinforced plastic includes, for example, a multilayer glass fiber fabric that is embedded in a cast resin molding material made of unsaturated polyester resin. The carrier layer 2 has, for example, a glass content of 54%, a weight per area of 1.65 kg/mm², and a thickness of 1 mm.

A first intermediate layer 3 is arranged above the carrier layer 2. The first intermediate layer 3 includes, for example, an adhesive film made of ethylene vinyl acetate (EVA) with a thickness of 0.4 mm.

A plurality of crystalline solar cells 4, of which three are depicted in FIG. 1B, are arranged above the first intermediate layer 3. The crystalline solar cell 4 consists, for example, of a monocrystalline silicon solar cell with a size of 156 mm×156 mm. All solar cells 4 of a solar module 1 according to the invention are electrically conductively connected to each other via busbars, in serial connection or parallel connection, depending on the intended use.

A second intermediate layer 5, which includes, for example, an adhesive film made of ethylene vinyl acetate (EVA) with a thickness of 0.4 mm, is arranged above the solar cells 4.

A front pane 6 is arranged above the second intermediate layer 5. The front pane 6 includes, for example, a low-iron soda lime glass with a thickness from 0.85 mm to 2.8 mm and, for example, of 1 mm. The soda lime glass is thermally partially prestressed with a prestress of, for example, 35 MPa. Partially prestressed glass is distinguished from prestressed glass by a slower cooling process. The slower cooling process results in lower voltage differences between the core and the surfaces of the glass. The bending strength of partially prestressed glass falls between that of non-prestressed and prestressed glass. Partially prestressed glass has, in the event of breakage, a high residual load-bearing capacity and is, consequently, particularly suitable for fall-prevention glazings on buildings or in the roof area.

The carrier layer 2 has a first coefficient of thermal expansion of, for example, 27×10⁻⁶/K. The front pane 6 has a second coefficient of thermal expansion of, for example, 9×10⁻⁶/K. The difference between the first and second coefficient of thermal expansion is 18×10⁻⁶/K and is thus 200% of the second coefficient of thermal expansion.

The carrier layer 2 has, in this exemplary embodiment, a peripheral projection 13 beyond the front pane 6. The width a of the projection is preferably from 0.5 cm to 10 cm and, for example, 2 cm. An edge reinforcement 7 is arranged above the projection 13 of the carrier layer 2 and above an edge region 9 of the front pane 6. The width b of the edge region 9 is preferably 0.5 cm to 10 cm and, for example, 1 cm. The edge reinforcement 7 includes one height-compensating, first edge reinforcement layer 7.1. The first edge reinforcement layer 7.1 is connected via an adhesive layer 14 and, for example, via a double-sided adhesive tape to the carrier layer 2. The thickness of the first edge reinforcement layer 7.1 is selected such that the top of the first edge reinforcement layer 7.1 and the top of the front pane 6 form a flush, flat surface. The first edge reinforcement layer 7.1 can even include a layer sequence of a plurality of layers and, for example, of two layers. The first edge reinforcement layer 7.1 can even include only an adhesive, for example, a double-sided adhesive tape, with the thickness of the adhesive tape compensating the height difference between carrier layer 2 and front pane 6.

A second edge reinforcement layer 7.2, overlapping the front pane 6 in sections, is arranged in sections above the first edge reinforcement layer 7.1 and above an edge region 9 of the front pane 6. The second edge reinforcement layer 7.2 ist bonded by an adhesive layer 15 to the first edge reinforcement layer 7.1 and to the edge region 9 of the front pane 6. The overlapping edge reinforcement layer 7.2 protects the sensitive outer edge region 9 of the front pane 6 against damage, for example, against hail impact. The edge reinforcement 7 extends above the front pane 6 by the height h of, for example, 1 mm.

The edge reinforcement 7 includes, for example, a glass fiber reinforced plastic and, for example, the same glass fiber reinforced plastic, from which the carrier layer 2 is made.

The edge reinforcement 7 with a first edge reinforcement layer 7.1 and a second edge reinforcement layer 7.2 can just as easily be made in one piece, for example, from a plastic such as polyurethane (PU). The edge reinforcement 7 can, for example, be produced by extrusion, injection molding, or reaction injection molding (RIM).

In an alternative embodiment of the solar module according to the invention, the carrier layer 2 and the front pane 6 are congruent and arranged one over the other without projection. The edge reinforcement 7 then includes only an overlapping, second edge reinforcement layer 7.2 and no height-compensating, first edge reinforcement layer 7.1.

FIG. 1C depicts a cross-sectional view along the section line B-B′ of FIG. 1A. A plurality of water drain channels 8.1, 8.2 in the form of cutouts are arranged in the second edge reinforcement layer 7.2. The water drain channels 8.1, 8.2 connect the internal edge 10 of the second edge reinforcement layer 7.2 to the extrenal edge 11 of the second edge reinforcement layer 7.2. The width d of the water drain channels 8.1, 8.2 is from 1 mm to 5 mm and, for example, 3 mm. The width d of the water drain channels 8.1, 8.2 and the thickness of the second edge reinforcement layer 7.2 are selected such that a hailstone with a diameter of 25 mm does not damage the front pane in the hail impact test. This can be determined in the context of simple experiments.

In the exemplary embodiment of a solar module 1 according to the invention depicted in FIG. 1A-C, a water drain channel 8.1 is in each case arranged in each corner 12 of the solar module 1. The water drain channels 8.1 are arranged, for example, at an angle of 45° relative to the external sides I, II, Ill, IV of the solar module 1. Moreover, each long external side II, IV of the solar module 1 has five water drain channels 8.2, and each short external side I, III of the solar module 1 has three water drain channels 8.2. The water drain channels 8.2 on the external sides I, II, III, IV of the solar module 1 are, for example, arranged perpendicular to the external sides I, II, III, IV of the solar module 1.

The solar module 1 according to the invention with a front pane 6 made of glass with a thickness of 1 mm has a weight per area of roughly 6 kg/m².

The busbars 21 include, for example, a metal foil made of tinned copper with a width of 5 mm and a thickness of 0.2 mm. The busbars 21 can have additional insulation, for example, a polyimide film, polyurethane (PU), or a buthyl rubber, in the region in which they protrude beyond the front pane (6).

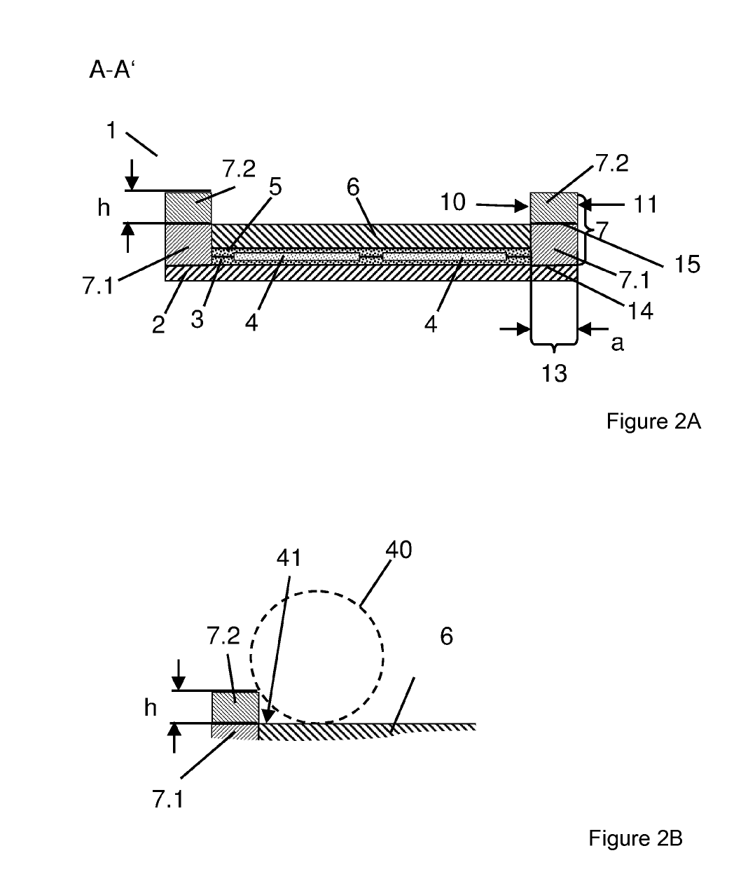

FIG. 2 A depicts a cross-sectional view of an alternative embodiment of a solar module 1 according to the invention along the section line A-A′ of FIG. 1A. The embodiment differs from the example of FIG. 1B in that the second edge reinforcement 7.2 does not overlap the front pane 6. The second edge reinforcement 7.2 extends by a height h beyond the front pane 6. The height h is, for example, 1 mm.

FIG. 2B depicts a detail of the edge of the solar module 1 of FIG. 2A. The outer region of a front pane 6 is especially susceptible to flaking or conchoidal fractures of the glass, for example, with striking of a hailstone 40 in the hail impact test. A protected region 41 is created by means of the superelevation h of the second edge reinforcement layer 7.2 beyond the front pane 6. A hailstone 40 with a diameter of, for example, 25 mm cannot advance into the especially damage susceptible region 41 of the front pane 6 because of the superelevation h of the second edge reinforcement layer 7.2. The height h can be determined by simple experiments in the hail impact test.

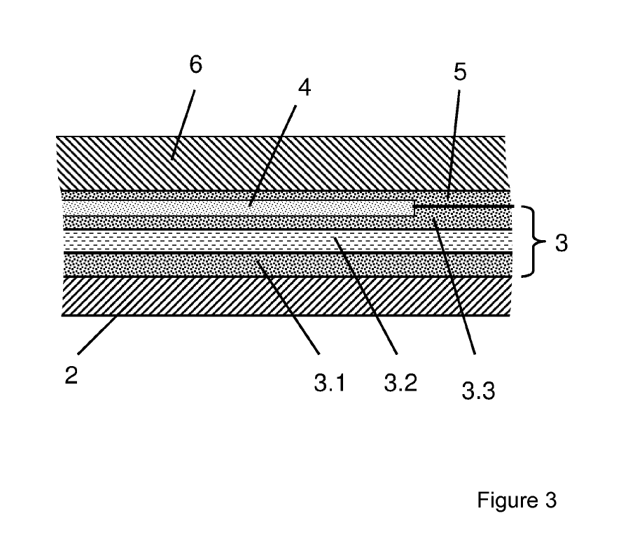

FIG. 3 depicts a cross-sectional view of the layer structure of an alternative exemplary embodiment of a solar module 1 according to the invention. The layer structure includes a carrier layer 2, a first intermediate layer 3, crystalline solar cells 4, a second intermediate layer 5, and a front pane 6. The carrier layer 2 includes, in this exemplary embodiment, a metal foil, for example, a foil made of a stainless high-grade steel such as Nirosta, material number 1.4016, with a thickness of 0.3 mm.

In an advantageous embodiment of the solar module 1 according to the invention, the first intermediate layer 3 includes a stack sequence of a first adhesive layer 3.1, an insulating layer 3.2, and a second adhesive layer 3.3. The first adhesive layer 3.1 and the second adhesive layer 3.3 include, for example, an adhesive film made of ethylene vinyl acetate (EVA) with a thickness of 0.4 mm. The insulating layer 3.2 includes a solid insulating film, for example, made of polyethylene terephthalate (PET) with a thickness of 50 μm. The insulating layer 3.2 has the task of insulating the busbars 21 and the back side of the solar solar cells 4 from the electrically conductive metal foil of the carrier layer 2. The electrical insulation by means of the additional insulating layer 3.2 is especially important since, in particular, unevennesses and solder joints of the solar cells 4 and busbars 21 can pierce a thin, comparatively soft intermediate layer of ethylene vinyl acetate (EVA) during the lamination process. This can result in short circuits and leakage currents in the solar module 1.

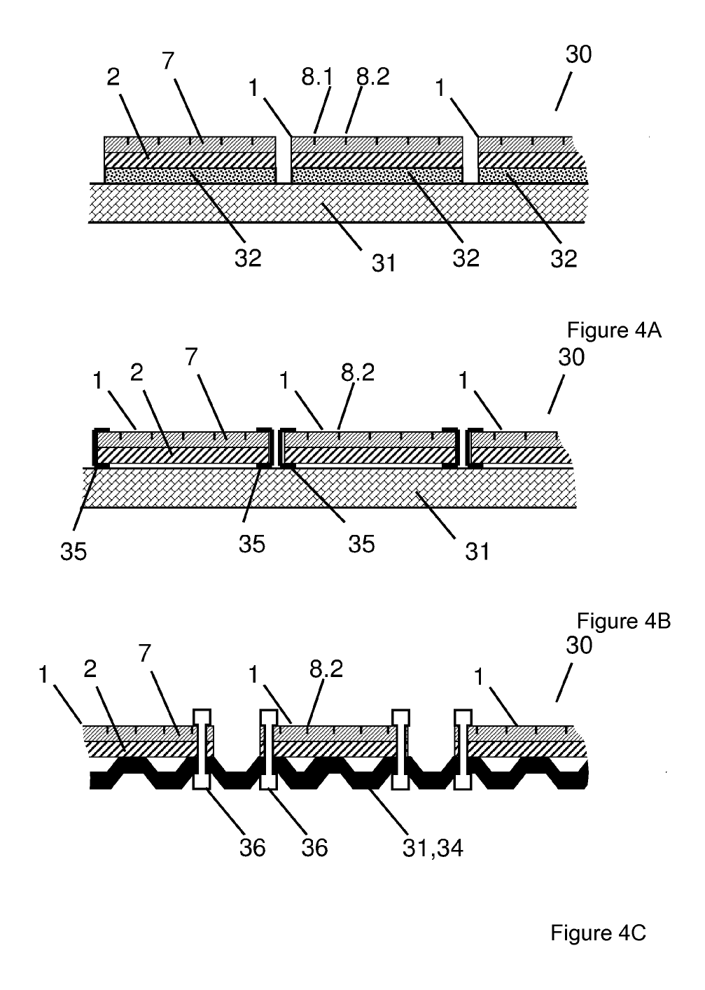

FIG. 4A depicts a cross-sectional view of a flat roof 30 according to the invention with solar modules 1 according to the invention. The solar modules 1 are depicted in a cross-section along the section line B-B′ of FIG. 1A. The roofing membrane 31 of the flat roof 30 according to the invention includes, for example, a membrane made of bitumen, polymer-modified bitumen, thermoplastic olefin elastomers (TPOs), or polyvinyl chloride (PVC). The solar modules 1 are in each case adhesively bonded to the roofing membrane 31 via an adhesive layer 32. The adhesive layer 32 includes, for example, buthyl, acryl, bitumen, silicone, or another weather-resistant adhesive. The roofing membrane 31 of the flat roof 30 has, for example, a pitch of 3°.

In the event of rain or snow melt, the water accumulating on the front pane can drain off via the water drain channels 8.1 and 8.2.

FIG. 4B depicts a cross-sectional view of an alternative embodiment of a flat roof 30 according to the invention. The solar modules 1 are depicted in a cross-section along the section line B-B′ of FIG. 1A. A plurality of U-shaped retaining rails 35 are fixedly connected to the roofing membrane 31 of the flat roof 30. The retaining rails 35 include, for example, a plastic or a metal such as aluminum. The solar modules 1 according to the invention are introduced on two opposing external sides I, III or II, IV into the U-shaped retaining rails and retained thereby.

FIG. 4C depicts a cross-sectional view of another alternative embodiment of a flat roof 30 according to the invention. The solar modules 1 are depicted in a cross-section along the section line B-B′ of FIG. 1A. The roofing membrane 31 includes a trapezoidal metal sheet 34 with high points, the so-called webs, and depressions situated therebetween, so-called corrugations. The distance from one corrugation center to the next is, for example, 207 mm. The profile depth, i.e., the height difference between web and corrugation is, for example, 35 mm. The trapezoidal metal sheet has a thickness of, for example, 0.75 mm and and is made from a galvanized steel sheet. The solar modules 1 are bolted to the trapezoidal metal sheet 34 in the region of the edge reinforcement 7 and in particular in the region of the projection of the carrier layer 2 beyond the front pane 6.

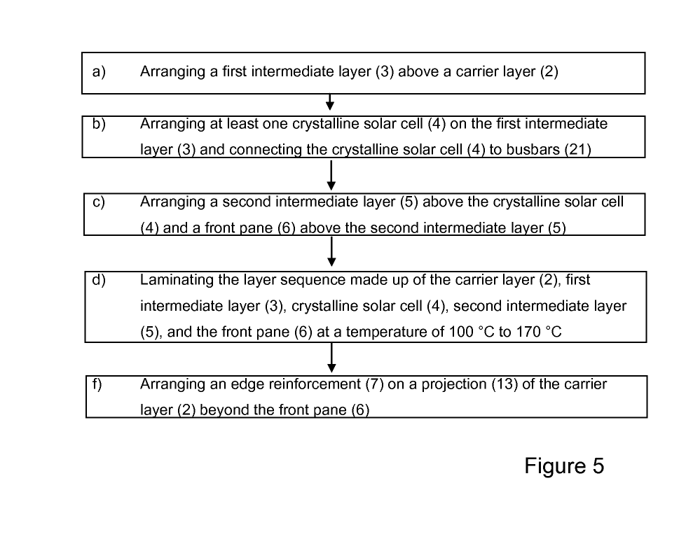

FIG. 5 depicts a detailed flow chart of the method according to the invention.

### REFERENCE CHARACTERS

1 solar module

2 carrier layer

3 first intermediate layer

3.1 first adhesive layer

3.2 insulating layer

3.3 second adhesive layer

4 crystalline solar cell, silicon solar cell

5 second intermediate layer

6 front pane

7 edge reinforcement

7.1 first edge reinforcement layer

7.2 second edge reinforcement layer

8.1, 8.2 water drain channel

9 edge region of the front pane 6

10 internal side of the edge reinforcement 7

11 external side of the edge reinforcement 7

12 corner of the solar module 1

13 projection of the carrier layer 2 beyond the front pane 6

14 adhesive layer

15 adhesive layer

20 connection housing

21 busbar

30 flat roof

31 roofing membrane

32 adhesive layer

34 trapezoidal metal sheet

35 retaining rail, U-shaped rail

36 screw connection

40 hailstone

41 region of the front pane 6

a width of the projection 13 of the carrier layer 2 beyond the front pane 6

b width of the edge region 9

d width of the water drain channel 8.1, 8.2

h height of the superelevation of the edge reinforcement 7 beyond the front pane 6

A-A′ section line

B-B′ section line

I, II, III, IV side, external side of the solar module 1

1. A solar module, comprising:
a carrier layer,
a first intermediate layer, which is arranged above the carrier layer,
at least one crystalline solar cell, which is arranged above the first intermediate layer,
a second intermediate layer, which is arranged above the at least one crystalline solar cell,
a front pane, made of glass with a thickness of 0.85 mm to 2.8 mm, arranged above the second intermediate layer, and
an edge reinforcement, wherein
the edge reinforcement projects beyond the front pane by a height of at least 0.5 mm and the edge reinforcement has on each corner of the solar module at least one water drain channel that connects an internal side and an external side of the edge reinforcement.

2. The solar module according to claim 1, wherein the edge reinforcement has on each external side of the solar module at least one water drain channel.

3. The solar module according to claim 1, wherein the at least one water drain channel has a width of 0.5 mm to 5 mm, preferably of 2.5 mm to 5 mm.

4. The solar module according to claim 1, wherein the edge reinforcement covers at least one peripheral edge region of the front pane of at least 0.2 cm, preferably of at least 0.5 cm.

5. The solar module according to claim 1, wherein the carrier layer has a peripheral projection beyond the front pane of at least 0.3 cm, preferably of 0.5 cm to 5 cm and particularly preferably of 1 cm to 2 cm and the edge reinforcement is arranged at least partially above a projection.

6. The solar module according to claim 1, wherein the at least one crystalline solar cell is a monocrystalline or polycrystalline solar cell and contains a doped semiconductor material, preferably made of silicon or gallium arsenide, or a tandem cell with a crystalline solar cell.

7. The solar module according to claim 1, wherein a difference between a first coefficient of thermal expansion of the carrier layer and a second coefficient of thermal expansion of the front pane is less than or equal to 300%, of the second coefficient of thermal expansion.

8. The solar module according to claim 1, wherein the carrier layer includes a glass fiber reinforced plastic with a first coefficient of thermal expansion of 7.3×10⁻⁶/K to 35×10⁻⁶/K.

9. The solar module according to claim 1, wherein the carrier layer includes a metal foil with a first coefficient of thermal expansion of 7.3×10⁻⁶/K to 10.5×10⁻⁶/K and the first intermediate layer includes a stack sequence of at least one first adhesive layer, one insulating layer, and one second adhesive layer.

10. A flat roof with a solar module, comprising:
a roofing membrane with a pitch of 1% to 23.1%, and
at least one solar module according to claim 1, arranged on the roofing membrane,
wherein the roofing membrane and the solar module are connected to each other at least in sections by at least one adhesive layer and/or connecting means.

11. The flat roof according to claim 10, wherein the solar module is bolted to the roofing membrane in a region of the edge reinforcement and/or is fastened by the connecting means.

12. A method for producing a solar module, comprising wherein at least:
arranging a first intermediate layer above a carrier layer,
arranging at least one crystalline solar cell on the first intermediate layer (3), and connecting the at least one crystalline solar cell to busbars,
arranging a second intermediate layer above the at least one crystalline solar cell and arranging a front pane above the second intermediate layer (5),
laminating the carrier layer, the first intermediate layer, the at least one crystalline solar cell, the second intermediate layer, and the front pane at a temperature of 100° C. to 170° C., and
arranging the edge reinforcement at least on a projection of the carrier layer beyond the front pane,
thus producing the solar module according to claim 1.

13. The method ) according to claim 12, wherein the arranging the edge reinforcement further comprises
extruding a strand with a cross-section of the edge reinforcement,
dividing the strand into segments, and
incorporating the at least one water drain channel into the segments.

14. The method according to claim 12, wherein the edge reinforcement is produced by reaction injection molding or by an injection molding process.

15. A method comprising:
using the solar module according to claim 1 on a flat roof, preferably a metal flat roof, of a building or of a vehicle for transportation on water, on land, or in the air.

16. A method comprising:
a using the solar module according to claim 1 on a flat roof with a pitch of 1% to 23.1%, preferably of 2% to 17.6%, particularly preferably of 5% to 8.8%.

17. The solar module according to claim 3, wherein the carrier layer has a peripheral projection beyond the front pane of 0.5 cm to 5 cm, preferably 1 cm to 2 cm.

18. The solar module according to claim 7, wherein the difference between the first coefficient of thermal expansion of the carrier layer and the second coefficient of thermal expansion of the front pane is less than or equal to 17% and preferably less than or equal to 7%.

19. The flat roof according to claim 11, wherein the connecting means is at least one retaining rail.
